(19) United States
(12) Patent Application Publication
(10) Pub. No.: US 2009/0243059 A1
(43) Pub. Date: Oct. 1, 2009

(54) Semiconductor package structure

(76) Inventor: Chin-Ti Chen, Hsinchu (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/081,664

(22) Filed: Apr. 21, 2008

(30) Foreign Application Priority Data
Mar. 28, 2008 (TW) 97111476

(51) Int. Cl. H01L 23/495

(52) U.S. Cl. 257/673; 257/E23.031

(57) ABSTRACT

A semiconductor package structure includes a carrier having a plurality of leads, wherein each of the leads is composed of an inner lead and an outer lead; a chip arranged on the bottom surface of the inner leads; an electrical connecting structure and a molding component. The invention discloses that the inner leads are bent outwardly from the horizontal at top surface of the chip to form a ladder-like difference and the outer leads are extended outwardly horizontally, thus a height difference formed between the chip and the outer lead prevents the particles from contacting the chip and the outer lead at the same time to enhance the electrical reliability of the chip.

### BACKGROUND OF THE INVENTION

1. Field of the Invention

The present invention generally relates to a semiconductor package structure, and more particularly relates to a lead structure for enhancing the electrical reliability of a packaged chip in a semiconductor package structure.

2. Description of the Prior Art

In semiconductor package process, leads are divided into inner leads and outer leads based on function. Generally, the inner leads are shorter and used for supporting the chip; the outer leads are longer and extending out of the molding component to electrically connect with the external electrical product. Besides, the inner leads are electrically connected to the chip with wires, so the forms of leads directly affect the wire bonding procedure and indirectly relates to the electric conductance of the chip. The leads therefore play an important role in electrical reliability of the chips.

FIG. 1 is cross-sectional view schematic diagram showing a semiconductor package structure of a prior art. As the figure shown, the lead 11 is composed of the inner lead 12 and the outer lead 14, wherein the outer lead 14 horizontally connects the inner lead 12 to extend outwardly. The chip 20 is mounted on the bottom surface of the inner lead 12 electrically connected to the chip 20 via the wire 30. However, during the process of thermal stress or package, the particles in the air fall into the molding component 40 and damage the chip 20 due to small thickness of interval h between the lead 11 and the chip 20, about 100 μm.

The thickness of the interval h easily causes the particles falling into the molding component 40 to contact with the lead 11 and the chip 20 at the same time and induce the additional electricity of the chip 20 to increase unnecessary current in device and the loading of the device of the chip 20 to damage the chip 20. Therefore, the issue of the particles falling into the molding component to damage the chip needs to be solved urgently.

### SUMMARY OF THE INVENTION

Other advantages of the present invention will become apparent from the following description taken in conjunction with the accompanying drawings wherein are set forth, by way of illustration and example, certain embodiments of the present invention.

In order to solve the issue mentioned-above, one objective of the present invention is to provide a semiconductor package structure, especially a semiconductor package structure with strengthened leads, wherein the inner lead is bent outwardly from the horizontal at the top surface of the chip to form a ladder-like difference and the outer lead is extended horizontally and outwardly from the inner leads so as a height difference is formed between the chip and the outer lead. The height difference prevents the particles falling into the molding component from contacting the chip and the lead at the same time to damage the electricity of the chip, so as to keep the quality of packaged chip efficiently.

In order to reach the objective mentioned-above, one embodiment of the present invention discloses a semiconductor molding component structure, including: a carrier having a plurality of leads set oppositely to form an opening, wherein each of the leads is composed of an inner lead and an outer lead; a chip arranged on the bottom surface of the inner leads at the area of the opening, wherein the inner leads are bent outwardly from the horizontal at the top surface of the chip to form a ladder-like difference and the outer leads are extended horizontally and outwardly from the inner leads so as a height difference is formed between the chip and the outer leads; an electrically connecting structure electrically connecting the chip and the inner leads; and a molding component covering the carrier and the chip to expose a portion of the outer leads to strengthen the lead structure.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG. 1 is a cross-sectional view schematic diagram showing a semiconductor package structure of a prior art; and

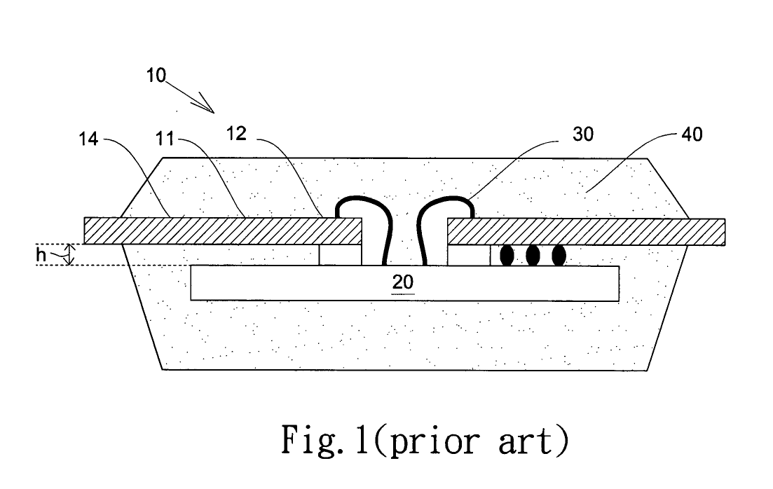

FIG. 2 is a cross-sectional view schematic diagram showing the semiconductor package structure according to one embodiment of the present invention.

### DESCRIPTION OF THE PREFERRED EMBODIMENT

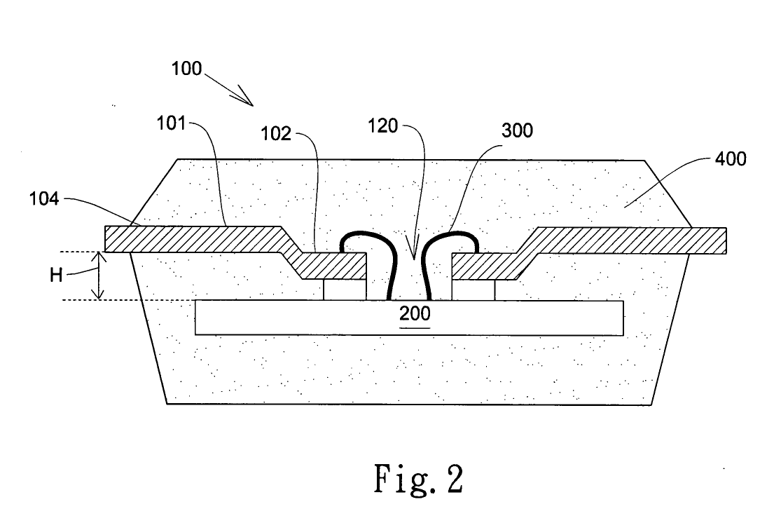

FIG. 2 is a cross-sectional view schematic diagram showing the semiconductor package structure according to one embodiment of the present invention. First of all, the present invention includes a carrier 101, a chip 200, an electrically connecting structure 300 and a molding component 400. The carrier 101 has a plurality of leads set oppositely to form an opening 120, wherein each of the leads is composed of an inner lead 102 and an outer lead 104. The chip 200 is arranged on the bottom surface of the inner leads 102 at the area of the opening 120, wherein the inner leads 102 are bent outwardly from the horizontal at the top surface of the chip 200 to form a ladder-like difference and the outer leads 104 are extended horizontally and outwardly from the inner leads 102 so as a height difference H is formed between the chip 200 and the outer leads 104. The electrically connecting structure 300 electrically connects the chip 200 and the inner lead 102. The molding component 400 covers the carrier 101 and the chip 200 to expose a portion of the outer leads 104.

In the present embodiment, the height difference H is larger than the diameter of the particles falling into the molding component 400 in general fabrication process. In this case, the height difference H may be utilized to prevent the particles from contacting the chip 200 and the outer lead 104 at the same time, inducing additional electricity and unnecessary current passing through the device in the chip 200, and damaging the chip 200 so that the function of the chip 200 can be efficiently maintained.

Continuing the description mentioned above, in the semiconductor package structure 100 of the present invention, wherein the top surface of the chip 200 is active and further includes a plurality of pads (not shown in the figure) for inner lead 102 to electrically connect thereto. Besides, the electrically connecting structure 300 includes a plurality of conducting wires such as the golden wires used to electrically connect the pads and the inner lead 102. In one embodiment, the electrically connecting structure 300 includes a plurality of conducting balls (not shown in the figure), e.g. solder balls. Moreover, the electrically connecting structure 300 are configured for connecting the necessary electrical conductance, therefore the height difference H formed between the outer leads 104 and the chip 200 of the present invention may efficiently restrain the particles falling into the molding component from messing up the electric conductance and damaging the chip structure.

In another embodiment, the present invention also mounts a plurality of pads (not shown in the figure) on the bottom surface of the chip 200 for the conducting wires or conducting balls to electrically connect the inner lead 102 with the pads on the chip 200.

To sum up the description mentioned above, the semiconductor package structure of the present invention includes a lead structure with a height difference formed between the chip and outer lead. The height difference prevents the particles falling into the molding component in the fabrication process from contacting with the lead and chip at the same time and conducting the electricity of each other to induce the additional current passing through the device of the chip to destroy the chip function. Therefore, the present invention enhances the reliability of packaged product efficiently.

While the invention is susceptible to various modifications and alternative forms, a specific example thereof has been shown in the drawings and is herein described in detail. It should be understood, however, that the invention is not to be limited to the particular form disclosed, but to the contrary, the invention is to cover all modifications, equivalents, and alternatives falling within the spirit and scope of the appended claims.

What is claimed is:

1. A semiconductor package structure comprising:
a carrier having a plurality of leads set oppositely to form an opening, wherein each of said leads is composed of an inner lead and an outer lead;
a chip arranged on the bottom surface of said inner leads at the area of said opening, wherein said inner leads are bent outwardly from the horizontal at the top surface of said chip to form a ladder-like difference, and said outer leads are extended horizontally and outwardly from said inner leads so as a height difference is formed between said chip and said outer leads;
an electrically connecting structure electrically connecting said chip and said inner leads; and
a molding component covering said carrier and said chip to expose a portion of said outer leads.

2. The semiconductor package structure according to claim 1, wherein said electrically connecting structure further comprises a plurality of conducting wires.

3. The semiconductor package structure according to claim 2, wherein the top surface of said chip has a plurality of pads.

4. The semiconductor package structure according to claim 3, wherein said conducting wires electrically connect to said pads and said inner leads.

5. The semiconductor package structure according to claim 1, wherein said electrically connecting structure comprises a plurality of conducting balls.

6. The semiconductor package structure according to claim 5, wherein the bottom surface of said chip has a plurality of pads.

7. The semiconductor package structure according to claim 6, wherein said conducting balls electrically connect said pads and said inner leads.
